(19) United States
(12) Patent Application Publication
(10) Pub. No.: US 2005/0136664 A1
(43) Pub. Date: Jun. 23, 2005

(54) Novel process for improved hot carrier injection

(75) Inventors: Tsai-Yuan Chien, Hsinchu City (TW); Pin-Yi Hsin, Chui-Bei City (TW)

Correspondence Address: DUANE MORRIS, LLP;IP DEPARTMENT, ONE LIBERTY PLACE, PHILADELPHIA, PA, 19103-7396, US

(73) Assignee: Taiwan Semiconductor Manufacturing Co.

(21) Appl. No.: 10/742,965

(22) Filed: Dec. 22, 2003

(51) Int. Cl. H01L 21/311; H01L 21/302; H01L 21/461

(52) U.S. Cl. 438/689; 438/694

(57) ABSTRACT

A method for fabricating aluminum bonding pads is described. A passivation layer is provided overlying semiconductor device structures in and on a substrate. A bonding pad layer is deposited overlying the passivation layer and within openings in the passivation layer to underlying semiconductor device structures. A masking layer is formed overlying the bonding pad layer wherein the masking layer has a pattern of bonding pads and a dummy pattern wherein a density of the bonding pad pattern and the dummy pattern together is 20% or more. The bonding pad layer is etched away where it is not covered by the masking layer to form bonding pads contacting the semiconductor device structures and dummy pads not contacting the semiconductor device structures wherein the pattern density of 20% or more reduces plasma damage by reducing an etching rate of the bonding pad layer compared to a pattern density of less than 20%.

### BACKGROUND OF THE INVENTION

(1) Field of the Invention

The present invention relates to methods of fabricating bonding pads, and more particularly, to methods of fabricating aluminum bonding pads with improved hot carrier injection in the fabrication of an integrated circuit device.

(2) Description of the Prior Art

In the fabrication of integrated circuits, the interconnection of devices is of importance. Bonding pads are typically used for this purpose. Often, aluminum is used as the material for bonding pads. During the plasma etching process to form these bonding pads, plasma charging occurs. Plasma charging is accumulative in most etching and deposition steps. A high enough plasma charging will result in hot carrier injection (HCI) into the gate oxide of underlying devices causing device failure. Copper wire is often used to connect to the aluminum bonding pads. Many copper metal lines are also often included in the aluminum bonding pad layer. Copper processes are easily affected by charging. Thus, any reduction of charging would be beneficial to aluminum and copper processes as well. HCI is used as one measure of integrated circuit reliability. For example, 0.2% device HCI failures per year might be chosen as a goal.

It is desired to provide a method of bonding pad fabrication that will result in a lowering of the HCI failure rate.

A number of patents discuss aluminum patterning. U.S. Pat. No. 6,413,863 to Liu et al discloses the formation of dummy aluminum pads to counteract the effect of theta phase propagation that occurs during AlCu etching. U.S. Pat. No. 5,899,706 to Kluwe et al discloses determining the pattern density of the most densely packed area and then adding dummy patterns to lower density areas to equalize the pattern density across the wafer to reduce etch process sidewall effects. U.S. Pat. No. 6,376,388 to Hashimoto teaches employing a dummy aluminum pattern so that the pattern pitch is the same across the wafer. This results in a microloading that is essentially the same across the wafer and uniform etching speeds. U.S. Pat. No. 6,462,428 to Iwamatsu shows a dummy aluminum pattern that allows CMP polishing without pre-etching. None of these patents address HCI effect.

### SUMMARY OF THE INVENTION

Accordingly, it is a primary object of the invention to provide an effective and very manufacturable process of fabricating bonding pads, such as aluminum bonding pads, in the fabrication of integrated circuits.

Another object of the present invention is to provide a method for fabricating bonding pads, such as aluminum bonding pads, wherein there is a reduced hot carrier injection failure rate of the resulting integrated circuit devices.

Yet another object of the present invention is to provide a method for fabricating bonding pads, such as aluminum bonding pads, wherein a dummy aluminum pattern reduces plasma charging and thereby improves hot carrier injection failure rates.

In accordance with the objects of this invention, a method for fabricating bonding pads, such as aluminum bonding pads, is achieved. A passivation layer is provided overlying semiconductor device structures in and on a substrate. A bonding pad layer is deposited overlying the passivation layer and within openings in the passivation layer to underlying semiconductor device structures. A masking layer is formed overlying the bonding pad layer wherein the masking layer has a pattern of bonding pads and a dummy pattern wherein a density of the bonding pad pattern and the dummy pattern together is 20% or more. The bonding pad layer is etched away where it is not covered by the masking layer to form bonding pads contacting the semiconductor device structures and dummy pads not contacting the semiconductor device structures wherein the pattern density of 20% or more reduces plasma damage by reducing an etching rate of the bonding pad layer compared to a pattern density of less than 20%.

Also in accordance with the objects of the invention, an integrated circuit device having improved hot carrier injection failure is achieved. The device comprises a passivation layer overlying semiconductor device structures in and on a substrate and a pattern of bonding pads and a dummy pattern overlying the passivation layer wherein the bonding pads extend through openings in the passivation layer to some of the semiconductor device structures and wherein a density of the bonding pad pattern and the dummy pattern together is 20% or more.

### BRIEF DESCRIPTION OF THE DRAWINGS

In the following drawings forming a material part of this description, there is shown:

FIG. 1 is a graphical representation of etching endpoint time as a function of pattern density.

FIGS. 2 through 6 are schematic cross-sectional representations of a preferred embodiment of the present invention.

### DESCRIPTION OF THE PREFERRED EMBODIMENTS

The process of the present invention provides a method for fabricating bonding pads, such as aluminum bonding pads, in such a way as to improve hot carrier injection (HCI) failure rate. The inventors have found that as pattern density increases, aluminum pad etching time decreases. FIG. 1 is a graph showing etching endpoint time as a function of pattern density. Line 11 shows the line connecting the data points. Line 13 shows the linear relationship found between endpoint time and pattern density. That is, as pattern density increases, endpoint time decreases.

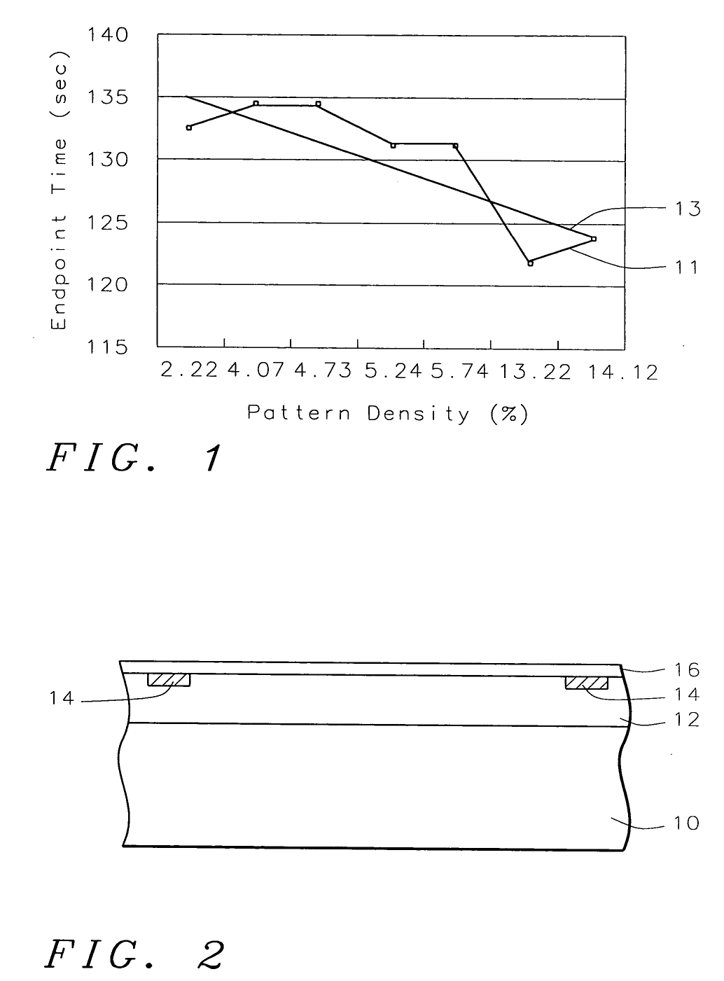

Referring now more particularly to FIG. 2, there is shown a partially completed integrated circuit device. The semiconductor substrate 10 is preferably composed of silicon having a (100) crystallographic orientation. Semiconductor substrate 10 may comprise other materials as is well known in the art. Semiconductor device structures are formed in and on the semiconductor substrate. For example, gate electrodes and associated source and drain regions, not shown, may be fabricated. Multiple layers of metallization and interconnections may be formed to complete the integrated circuit chip. Layer 12 represents all of these semiconductor device structures and interconnections. A passivation layer 16 is formed over the semiconductor device structures, using conventional processes.

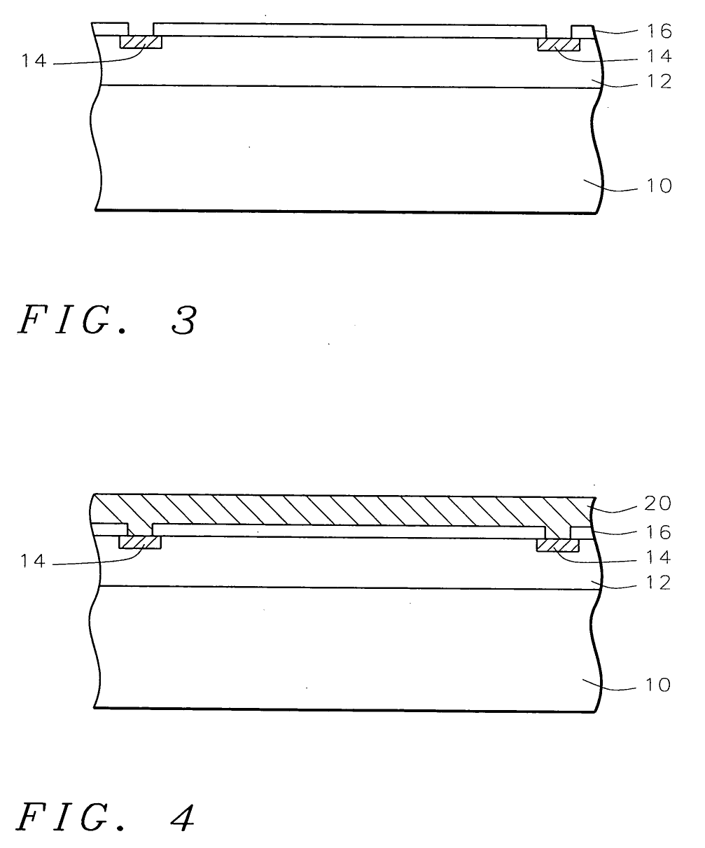

Structures 14 are representative of devices to be contacted by subsequently formed bonding pads. Openings are etched through the passivation layer 16 to the device structures 14 to be contacted by the bonding pads, as shown in FIG. 3.

Referring now to FIG. 4, a layer of aluminum 20, for example, is deposited over the passivation layer 16 and within the openings, for example by sputtering or other conventional methods. Preferably AlCu is the bonding pad material, but those skilled in the art will understand that other bonding pad material that substantially serves the function of aluminum layer 20 may also be used. The normal pattern density of bonding pads is between about 2 and 15%. The inventors have found that increasing the pattern density to about 20% or more will significantly reduce plasma charging.

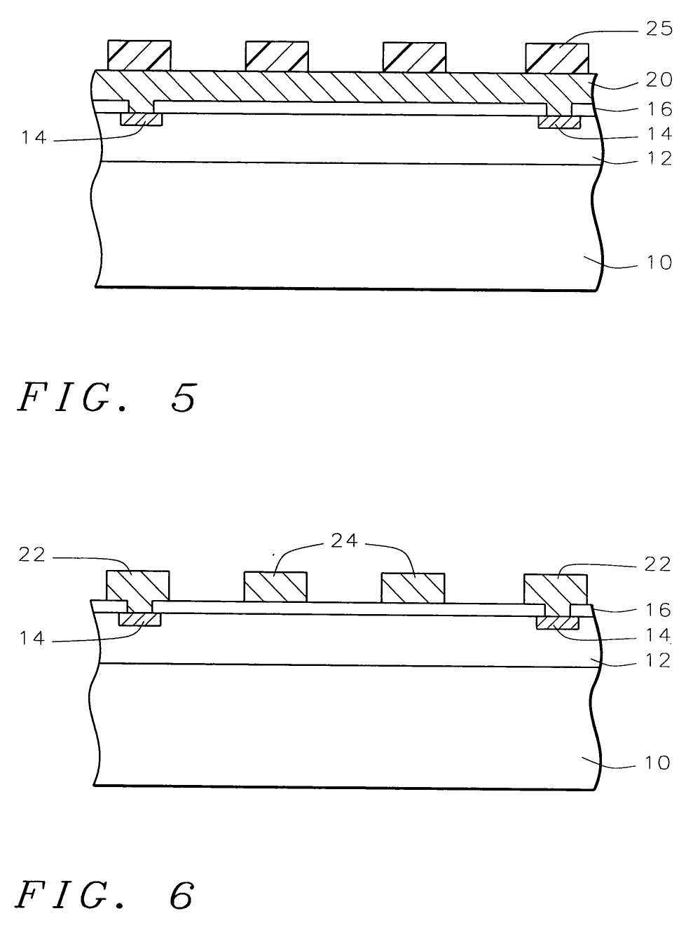

As illustrated in FIG. 5, for example, a photoresist mask 25 is formed over the aluminum layer 20. The pattern includes dummy pattern areas between the functional bonding pad pattern so that the pattern density is about 20% or more. With the dummy pattern, the etching time is decreased significantly, resulting is reduced plasma charging and therefore, an improvement in HCI failure. For example, an etching time of 130 seconds for a normal bonding pattern is reduced to about 46 seconds for a pattern density of about 50%. A pattern density of about 20% will result in an etching time of about 100 seconds.

Additionally, a higher power is beneficial. Typically, a bias power of about 260 watts is applied during etching. A higher bias power of about 300 watts results in lower HCI failure. However, simply an increase in power without the increased pattern density does not provide enough of an improvement in HCI failure. The increased pattern density of the present invention provides the desired HCI failure improvement.

FIG. 6 shows the bonding pads 22 and the dummy non-functional aluminum pads 24. Processing continues as is conventional in the art to provide connections to the bonding pads 22.

The process of the present invention provides a method for improving HCI failure rates. A dummy bonding pad pattern is provided so that etching time is decreased. This results in a reduction of plasma charging damage and thereby results in improved HCI failure rates.

While the invention has been particularly shown and described with reference to the preferred embodiments thereof, it will be understood by those skilled in the art that various changes in form and details may be made without departing from the spirit and scope of the invention.

1. A method for fabricating an integrated circuit device comprising:
providing a passivation layer having openings overlying semiconductor device structures in or on a substrate;
depositing a bonding pad layer overlying said passivation layer and within said openings to underlying said semiconductor device structures;
forming a masking layer overlying said bonding pad layer wherein said masking layer has a pattern of bonding pads and a dummy pattern wherein a density of said bonding pad pattern and said dummy pattern together is 20% or more; and
etching away said bonding pad layer where it is not covered by said masking layer to form bonding pads contacting said semiconductor device structures and dummy pads not contacting said semiconductor device structures.

2. The method according to claim 1 wherein said semiconductor device structures comprise gate electrodes and one or more layers of metal interconnections.

3. The method according to claim 1 wherein said bonding pad layer comprises aluminum.

4. The method according to claim 1 wherein said bonding pad layer comprises AlCu.

5. The method according to claim 1 wherein said masking layer comprises a photoresist layer.

6. The method according to claim 1 wherein said density is more than 50%.

7. The method according to claim 1 wherein during said etching step, a bias power of about 300 watts is applied.

8. A method for fabricating an integrated circuit device comprising:
providing a passivation layer having openings overlying semiconductor device structures in or on a substrate;
depositing a bonding pad layer overlying said passivation layer and within said openings to underlying said semiconductor device structures;
forming a masking layer overlying said bonding pad layer wherein said masking layer has a pattern of bonding pads and a dummy pattern wherein a density of said bonding pad pattern and said dummy pattern together is 20% or more; and
etching away said bonding pad layer where it is not covered by said masking layer to form bonding pads contacting said semiconductor device structures and dummy pads not contacting said semiconductor device structures wherein said pattern density of 20% or more reduces plasma damage by reducing an etching rate of said bonding pad layer compared to a pattern density of less than 20%.

9. The method according to claim 8 wherein said semiconductor device structures comprise gate electrodes and one or more layer of metal interconnections.

10. The method according to claim 8 wherein said bonding pad layer comprises aluminum.

11. The method according to claim 8 wherein said bonding pad layer comprises AlCu.

12. The method according to claim 8 wherein said masking layer comprises a photoresist layer.

13. The method according to claim 8 wherein said density is more than 50%.

14. The method according to claim 8 wherein during said etching step, a bias power of about 300 watts is applied.

15. An integrated circuit device comprising:
a passivation layer having openings overlying semiconductor device structures in or on a substrate; and
a pattern of bonding pads and a dummy pattern overlying said passivation layer wherein said bonding pads extend through said openings to some of said semiconductor device structures and wherein a density of said bonding pad pattern and said dummy pattern together is 20% or more.

16. The device according to claim 15 wherein said semiconductor device structures comprise gate electrodes and one or more layers of metal interconnections.

17. The device according to claim 15 wherein said pattern of bonding pads and said dummy pattern comprise aluminum.

18. The device according to claim 15 wherein said pattern of bonding pads and said dummy pattern comprise AlCu.

19. The device according to claim 15 wherein said density is more than 50%.

20. The device according to claim 15 wherein hot carrier injection failure of said device is lower than that of a device having a density of less than 20%.
